(19) United States
(12) Patent Application Publication
(10) Pub. No.: US 2026/0107599 A1
(43) Pub. Date: Apr. 16, 2026

(54) SYSTEMS AND METHODS RELATING TO INTERCONNECT STRUCTURES FOR SEMICONDUCTOR DEVICES

(71) Applicant: Taiwan Semiconductor Manufacturing Company, Ltd., Hsinchu (TW)

(72) Inventor: Ke-Jing Yu, Hsinchu (TW)

(73) Assignee: Taiwan Semiconductor Manufacturing Company, Ltd., Hsinchu (TW)

(21) Appl. No.: 18/917,303

(22) Filed: Oct. 16, 2024

(51) Int. Cl. H01L 27/146; H01L 23/00; H01L 23/528; H01L 23/532

(52) U.S. Cl. CPC H10F 39/809; H10F 39/018; H10F 39/811; H10W 20/43; H10W 20/4405; H10W 20/4421; H10W 20/4441; H10W 72/944; H10W 72/952; H10W 80/743; H10W 90/792

(57) ABSTRACT

A device may include a substrate comprising a plurality of first contact pads disposed on a first surface, and a plurality of second contact pads disposed on a second surface, the substrate comprising a plurality of interconnect structures extending between the first surface and the second surface. A device may include a first portion of an axial extension of the plurality of interconnect structures having sidewalls of a first profile. A device may include a second portion of the axial extension of the plurality of interconnect structures having sidewalls of a second profile, shallower than the first profile.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. More recently, improvements to device density increasingly relate to three dimensional features, such as combinations of various substrates (e.g., stacked wafers of a three-dimensional integrated circuit, 3DIC).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross sectional view of a semiconductor device, in accordance with some embodiments.

FIG. 2 illustrates a cross sectional view of interconnect structures, in accordance with some embodiments.

FIGS. 3-12 depict top and side views of various alignments between interconnect structures and contact pads, in accordance with some embodiments.

FIGS. 13 and 14 depict top views of an arrangement for interconnect structures and contact pads for a gate, drain, and source of a transistor, in accordance with some embodiments.

FIGS. 15 and 16 depict top views of another arrangement for interconnect structures and contact pads for a gate, drain, and source of a transistor, in accordance with some embodiments.

FIGS. 17 and 18 depict additional top views of a further arrangement for interconnect structures and contact pads for a gate, drain, and source of a transistor, in accordance with some embodiments.

FIGS. 19 and 20 depict top views of a yet another arrangement for interconnect structures and contact pads for a gate, drain, and source of a transistor, in accordance with some embodiments.

FIGS. 21 and 22 depict top views of another arrangement still, for interconnect structures and contact pads for a gate, drain, and source of a transistor, in accordance with some embodiments.

FIG. 23 illustrates a flow chart of a method for fabricating a semiconductor device, in accordance with some embodiments.

FIG. 24 illustrates a flow chart of a method for operating a camera system, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising”or other open terminology can include additional items.

Three-dimensional integrated circuits (3DIC) include multiple layers of electronic circuits vertically stacked and interconnected to form a semiconductor device. This approach offers significant benefits over traditional two-dimensional (2D) ICs, including higher density and reduced inter-circuit latency. However, 3DICs this increase in density may relatively high densities of interconnects. These interconnects can include interconnects similar to those found on 2DIC, as well as vertical interconnects to distribute power and data signals between the various stacked circuits. It may be challenging to route the various interconnects between and within the various circuits of a 3DIC.

In general, a vertical interconnect structure can couple to contact pads of various substrates of a 3DIC. For example, the interconnect structure can include an interlayer via (ILV), (e.g., a through-substrate-via (TSV), as may sometimes also be referred to as a through-silicon-via without limiting effect). The TSV or other interconnect structure can extend along an axial length between the contact pads coupled at its ends. The opposite ends of the interconnect structure can include different lateral dimensions (a relatively wide foot disposed opposite from a relatively narrow tip). Accordingly, a lateral dimension of the interconnect structure proximal to one end (e.g., the narrow tip) can be configured to extend through high-density environments such as dense metallization layers, well regions (e.g., P-wells or N-wells), or shallow trench isolation (STI) regions. A lateral dimension of the interconnect structure, proximal to an opposite end of the interconnect structure (e.g., the foot) can be configured to provide a robust, low resistance connection with a further substrate.

In some embodiments, the 3DIC includes a camera system. For example, a first substrate of the 3DIC can include image sensors. The image sensors can be coupled with an image signal processor of another substrate. A density of the image sensors may be limited by an available number (or current carrying capacity) of interconnect network connections. For example, the interconnect network can include various metallization lines and via structures, including TSV interconnect structures. A TSV interconnect structure, at a first end (e.g., the narrow tip), can be configured to interface with the image sensors via a metallization layer, as may aid in providing connectivity to image sensors arranged in a high-density configuration. A second end (e.g., the foot) of the TSV can be configured to interface with another contact pad, as may decrease resistance or electromigration risk, or increase yields of the semiconductor device.

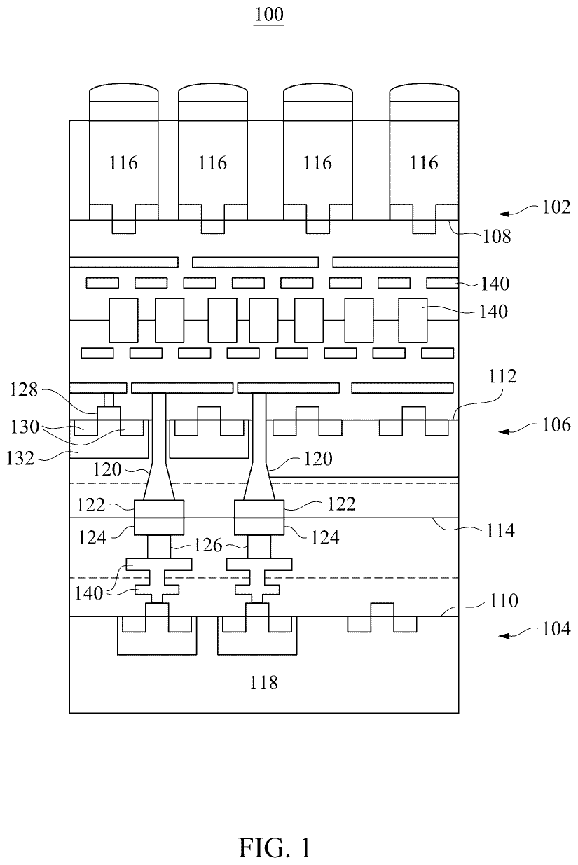

FIG. 1 illustrates a cross sectional view of a semiconductor device 100, in accordance with some embodiments. The semiconductor device 100 includes a first substrate 102 coupled with a second substrate 104 via an interconnect network including interconnect structures 120 along with other conductive elements of metallization layers of the respective substrates 102, 104. In some embodiments, the interconnect structures 120 coupling the first substrate with the second substrate extend through a third substrate 106 disposed between the first substrate 102 and the second substrate 104. That is, the interconnect structures 120 can include TSVs or other through-substrate interconnects.

In some embodiments, the semiconductor device 100 is a sensing system (e.g., of a camera system). The first substrate 102 can include various image sensors 116. For example, the image sensors 116 can include charge-coupled devices (CCD), complementary metal-oxide-semiconductor sensors (CMOS), or other sensor technologies. According to such a system, the proximity of the (image) sensors 116 to the (image) signal processor 118 can reduce the effects of signal distortion from transmission line asymmetries, environmental or system noise, or so forth. Such an illustrative example should not be construed as limiting. Embodiments of the present are not limited to camera devices; the systems and methods of the present disclosure may be useful for various memories, compute devices, non-camera sensor systems, or other high-density semiconductor devices.

In some embodiments, a density of the image sensors 116 is constrained by connections of an interconnect network. For example, a number of image sensors 116 (corresponding to a number of megapixels of a camera system) may be limited by a number of connections with the image signal processor (ISP) 118. Relatedly, a range of values of a particular one of the image sensors 116 may be limited by a current carrying capacity of the interconnect structure 120 (e.g., corresponding to a current passed between the image sensor 116 and the ISP 118). Thus, some efforts to improve image quality at the pixel level may tend to increase dimensions of interconnect structures 120, resulting in decreased pixel density, while efforts to increase image quality according to a density of pixels may tend to decrease dimensions of interconnect structures 120.

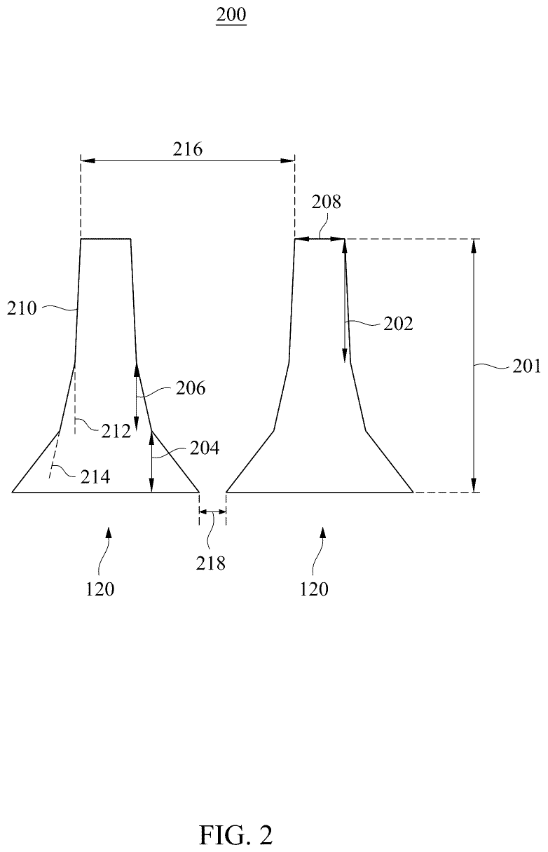

The second substrate 104 can include the ISP 118, the ISP 118 coupled with the image sensors 116 via interconnect structures 120 extending, axially between the first substrate 102 and the second substrate 104. Some example geometries for the interconnect structures 120 are provided at, for example, FIG. 2 henceforth. As is depicted in FIG. 1, a first (upper) portion of the axial extension of the interconnect structures 120 includes sidewalls of a first profile (depicted as generally vertical, as for a rectangular prism or cylindrical cross section). A second (lower) portion of the axial extension of the interconnect structures 120 have sidewalls of a profile which is shallower than the first profile. This portion is sometimes referred to as a foot.

The first substrate 102 and third substrate 106 may be coupled in a front-to-front configuration, wherein a surface 108 of the first substrate 102 having metallization layers formed thereover faces a surface 112 of the second substrate 102 having metallization layers formed thereover. The first substrate 102 and third substrate 106 can be coupled via connections between their respective metallization layers. For example, each of the metallization layers, starting from the substrate surfaces 108, 112 may be referred to as a M0, M1, M2 layer, and so forth until reaching an uppermost layer. The uppermost layers of the first substrate 102 and third substrate 106 can be coupled to one another. Each of the metallization layers can include lateral conductive elements (traces 140) coupled with via structures, such that the image sensors 116 can couple with transistors disposed on the third substrate 106. The transistors can adjust a gain of a signal passed from the image sensors 116 to the ISP 118. In some embodiments, the ISP 118 can modulate the operation of the transistor via control signals. Either of the image sensor signals or the control signals can be passed along the interconnect structure 120.

The second substrate 104 can couple with the third substrate 106 in a front-to-back configuration. As depicted, a backside (e.g., surface 114 opposite from the front surface 112) of the third substrate 106 is coupled with metallization layers of the second substrate 104. For example, the third substrate 106 can include contact pads 122 coupled with the interconnect structures 120, and the second substrate 104 can include corresponding contact pads 124. The contact pads 124 of the second substrate 104 can couple with the ISP 118 along a one or more alternating via structures 126 and lateral conductive elements (sometimes referred to as traces 140) of the metallization layers formed over a surface 110 of the second substrate 104.

Any of the substrates can include transistors disposed along an active surface. For example, the first substrate 102 can include reset transistors; the second substrate 104 can include digital or analog signal processing or memory transistors; and the third substrate can include source follower transistors (buffer transistors), or selection transistors for the image sensors 116. Each transistor can include a gate structure 128, and source/drain 130, each of which may be coupled with an interconnect structure 120 by via structures and other conductive elements (e.g., lateral traces 140) of the metallization layers. Further, the various substrates can include isolation or other features such as a well region 132. According to a proximal connection between an interconnect structure 120 and the gate structure 128 or source/drain 130, the interconnect structure 120 can pass near the well region 132 (e.g., between adjoining well regions 132). In some embodiments, a lateral distance between the well region 132 and the interconnect structure 120 is at least half of the lateral dimension of the upper portion of the interconnect structure 120 (e.g., half of the uppermost lateral dimension 208 of FIG. 2, hereinafter). For example, the interconnect structure 120 can pass within one micrometer (μm) of at least one well region 132, in some embodiments. Accordingly, the transistor density may be improved according to reductions in a portion of the interconnect structure 120 (e.g., the uppermost portion) proximal to the transistors.

In some embodiments, a foot of the interconnect structure 120 can extend laterally, greater than a spacing between features such as adjoining well regions 132 or traces 140. Accordingly, the stepped profile of the “foot” of the interconnect structure 120 can increase density relative to other approaches which may interfere with (e.g., couple with or contact) the well regions 132 (e.g., a vertical or continuously tapered profile).

FIG. 2 illustrates a cross sectional view 200 of interconnect structures 120, in accordance with some embodiments. A total vertical dimension 201 of the interconnect structures 120 can extend for a distance of a semiconductive substrate (e.g., a silicon wafer or die). For example, the total vertical dimension 201 can extend for more than fifty micrometers (μm). A first portion 204 of the vertical dimension 201 extends for greater than about thirty-five μm, in some embodiments. A second portion 206 extends for between about four μm and nine μm, in some embodiments. A third portion 202 extends for between about one μm and five μm, in some embodiments.

A majority of the vertical dimension (e.g., the third portion 202) extends with substantially parallel sidewalls 210. For example, the sidewalls 210 may extend between the foot and an opposite end of the interconnect structures 120 according to a negative taper of less than one degree (e.g., zero degrees). In some embodiments, the depicted cross-sectional views may be substantially symmetrical about the axis of the interconnect structures 120 (e.g., the interconnect structures 120 may be cylindrical). In some embodiments, the cross-sectional views may be substantially symmetrical about at least one angle of rotation (e.g., the interconnect structures 120 may be a rectangular prism, which is truncated according to tapered sidewalls). In some embodiments, only a portion of the sidewalls may be tapered (e.g., two opposite sides of a truncated rectangular prismatic body of the interconnect structure 120).

A first portion of the vertical dimension 204 (which may sometimes be referred to as a foot or footing) includes sidewalls which exhibit greater taper than an uppermost portion (depicted herein as a third portion 202 of the total vertical dimension 201). For example, sidewalls of the first portion 202 can exhibit negative taper 214 of greater than one degree (e.g., between about one degree and about ten degrees). Accordingly, a lateral dimension of the base of the foot can exceed other portions of the interconnect structures 120. The various portions of the interconnect structures 120 may correspond to separate etching operations or sub-operations. For example, in some embodiments, the uppermost portion may be formed according to a relatively anisotropic process (e.g., Bosch process), while the foot or other adjacent portions may be formed according to another directional or isotropic process. That is, an opening for the interconnect structures 120 may be formed according to a multi-step removal process (e.g., multi-step etching process).

A second portion of the vertical dimension 206 is disposed between the first portion 204 and the third (uppermost) portion 202. Sidewalls of the second portion 206 can exhibit negative taper 212 greater in magnitude than the first portion 204 and lesser in magnitude than the third portion 202. In some embodiments, the negative taper 212 of the second portion 206 is between about one degree and about five degrees. In some embodiments, the second portion 206 is omitted. In some embodiments, additional portions may be formed between the first portion 204 and the uppermost end of the interconnect structures 120. The additional portions can reduce an angle of deviation between the portions, as may avoid non-uniform etching, impedance mismatches, electromigration, etc. Each portion can correspond to a separate step of a stepped profile for a foot. In some embodiments, each step may be formed according to a separate process (e.g., etching process associated with a level of isotropy corresponding to the sidewall profile).

In some embodiments, a pitch 216 between adjacent interconnect structures 120 can be provided as less than about seven μm (e.g., between about three μm and seven μm). An uppermost lateral dimension 208, sometimes referred to as a critical dimension (CD) of the interconnect structure 120 can be less than five μm (e.g., between about 0.5 μm and five μm). An inter-foot spacing 218 can correspond to the pitch 216, less a lateral dimension of the foot. For example, the foot can include a dimension which is larger than the uppermost lateral dimension 208 (e.g., is greater than 10 percent larger, such as about 30% larger, about 50% larger, or greater, in some embodiments). For example, an illustrative example of an interconnect structure 120 can include an uppermost lateral dimension 208 of about three μm, and the foot can include a corresponding lateral dimension of about five μm.

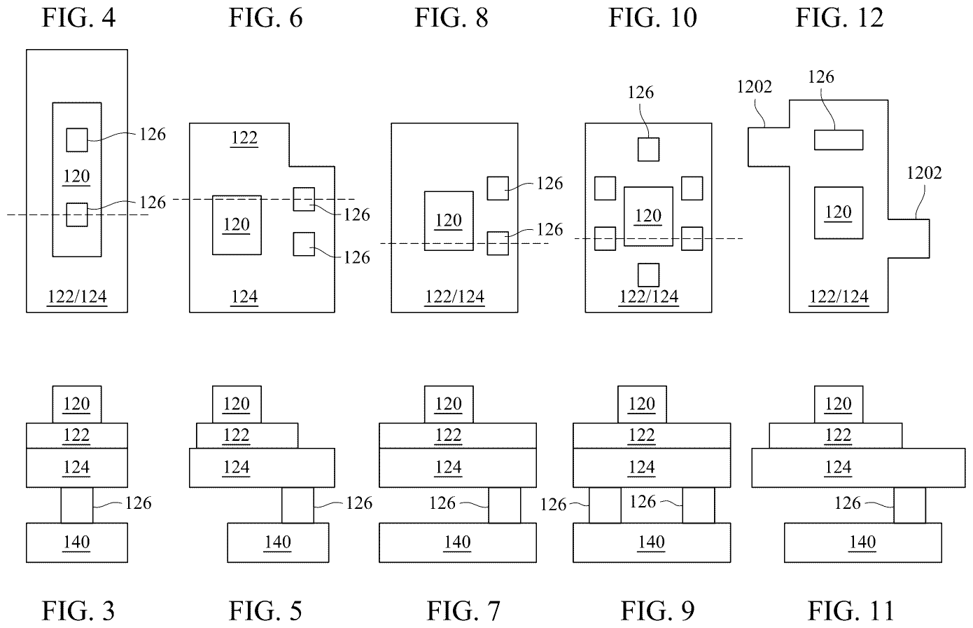

Referring generally to FIGS. 3-12, top and side views of various alignments between interconnect structures 120 and contact pads 122, 124 are provided, in accordance with some embodiments. For example, FIGS. 3 and 4 can provide respective side and top views of a same assembly; FIGS. 5 and 6 can provide respective side and top views of another same assembly; FIGS. 7 and 8 can provide respective side and top views of yet another same assembly; FIGS. 9 and 10 can provide respective side and top views of a further same assembly; FIGS. 11 and 12 can provide respective side and top views of a further same assembly still.

Referring particularly to the side view of FIG. 3, a detail view of a stack-up is provided. For example, the stack-up can match a stack-up between the second substrate 104 and third substrate 106 of FIG. 1. The stack-up includes a foot of the interconnect structure 120. Although depicted with substantially vertical sidewalls for the clarity of the figures (e.g., FIGS. 3, 5, 7, 9, and 11), the sidewalls of the interconnect structure 120 may exhibit negative taper in at least some embodiments of the present disclosure. The interconnect structure 120 is landed with a contact pad 122 of a same substrate (e.g., the third substrate 106 of FIG. 1). The interconnect structure 120 and the contact pad 122 can be or include a same or different material, some examples of which are provided henceforth with reference to FIG. 4. That contact pad 122 is coupled with a further contact pad 124 of another substrate. For example, the other substrate can be coupled with the rear surface 114 of the substrate including the interconnect structure 120. That contact pad 124, in turn, can couple with another substrate (e.g., a second substrate 104 including an ISP 118, in some embodiments). For example, the contact pad 124 can couple with transistors of an ISP 118 through a via structure 126 and traces 140 of a metallization layer disposed along a surface of a semiconductive portion of the second substrate 104.

Referring particularly to the top view of FIG. 4, the view is provided as a transparency view to depict the relative lateral positions of the various stack-up elements. The hidden portions of the interconnect structure 120 are continuous, according to some embodiments. Accordingly, the foot of the interconnect structure 120 can couple with the surface of the upper contact pad 122 over a lateral surface thereof, as may reduce a resistance of the contact interface. Further, any misalignments, over etch, interconnect structure 120 voids, or other manufacturing variances may be tolerated without affecting operation of the semiconductor device 100. For example, heating and current density at the interface between the interconnect structure 120 and adjacent contact pad 122 may be reduced relative to other approaches, as may result in lower electromigration and longer device lifetimes.

The hidden portions of the contact pads 122, 124 are continuous, according to some embodiments. Accordingly, the lower contact pad 124 may be referred to as laterally enveloping the depicted via structure 126. The via structure 126 may be a via of an uppermost metallization layer formed over the second substrate 104. Further, multiple of the via structures 126 may be provided (all of which are laterally enveloped by the contact pad 124, according to the depicted embodiment). Moreover, the via structures 126 are provided as vertically aligned with at least a portion of the interconnect structure 120, as may reduce path resistance between the interconnect structure 120 and the traces 140, and may further reduce noise or other signal variation due to the shorter, straighter, and lower resistance vertical path.

In some embodiments, various of the conductive elements provided herein, including the interconnect structure 120, via structures 126, traces 140, or gate structures 128 can include same or similar materials. However, when including same materials, the portions can be formed according to separate etching and deposition operations, leading to a presence of an interface which may exhibit contact resistance or other non-uniformity. Accordingly, electrical properties of the interface may be particularly important at these interfaces, especially in the presence of manufacturing variances. Further, in some embodiments, the various conductive elements can include different materials. For example, the materials for the interconnect structure 120 can include tungsten, aluminum, or copper; the materials for the via structures 126 and traces 140 can include copper or aluminum. The gate structures 128 can include various metal or polysilicon (PO) gates. In various embodiments, every combination of these materials is contemplated. Further, some materials can include separate materials, such as for alloys, or for using different materials for separate metallization layers.

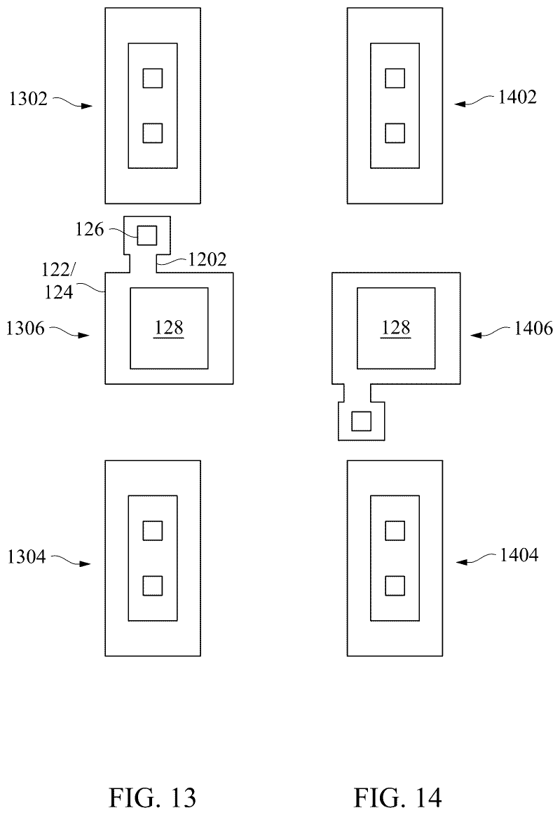

Referring particularly to the side view of FIG. 5, the via structure 126 is not aligned, along a vertical axis, with the interconnect structure 120. Indeed, no portion of the via structure 126 and the interconnect structures 120 laterally overlap. Accordingly, currents flowing between the via structure 126 and the interconnect structure 120 will travel laterally, along (and between) the contact pads 122, 124. Still, at least the contact pad 124 proximal to the via structure 126 laterally envelopes the via structure(s) 126. Such a geometry may reduce contact resistance, electromigration, etc., as described above, relative to other implementations such as a trace connection (e.g., as shown for the connections to the gate structure 128 depicted in FIGS. 13-22).

Referring particularly to the top view of FIG. 6, the contact pads 122, 124 are depicted as not aligned over an entire surface, but including substantial overlap (e.g., overlapping/in contact along greater than 50% of their area), according to the transparent view. Moreover, the upper contact pad 122 laterally envelopes the interconnect structure 120. In some embodiments, the contact pads 122, 124 include or consist of a same material, and at least one of the via structure 126 or interconnect structure 120 include a different material. Accordingly, increasing the contact area for the dissimilar materials may be more strongly correlated with a yield or performance of the device, than between the like materials of the contact pads 122, 124.

Referring particularly to the side view of FIG. 7, as for FIG. 5, the via structure 126 is not aligned, along a vertical axis, with the interconnect structure 120. However, the contact pads 122, 124 are depicted as congruent. Such an embodiment may prove less sensitive to substrate-substrate misalignment, but can occupy more space in a metallization layer, for the larger surfaces of the contact pads 122, 124, relative to FIG. 5. Referring particularly to the top view of FIG. 8, the rectangular contact pads 122, 124 are depicted as laterally coextensive with each other as described with regard to FIG. 7.

Referring particularly to the side view of FIG. 9, multiple via structures 126 are depicted. For example, two via structures 126 are depicted according to the depicted cut view. Referring particularly to the top view of FIG. 10, six via structures 126 are visible. The increased number of via structures 126, can further reduce electromigration, resistance, and vulnerability of the stack-up structure to manufacturing variances (e.g., voids, over etch, etc.).

Referring particularly to the side view of FIG. 11, a similar profile is provided as in FIG. 5 or FIG. 7. However, as can be seen according to the transparent top view of FIG. 12, the via structures 126 are asymmetric, extending longer in a direction perpendicular to the cut line of FIG. 11, than the depicted width of FIG. 11. Such a via structure 126 can provide certain of the benefits of multiple vias in a more compact setting. Although the various via structures 126 of FIG. 3-12 are provided as rectangular via structures (e.g., non-square rectangular for FIGS. 11-12 and square rectangular for FIGS. 3-10), via structures 126 can be provided according to various geometries. For example, in some embodiments, the via structures 126 (or the contact pads 122, 124, and interconnect structures 120) may be provided as substantially cylindrical.

In some embodiments, as is depicted in FIG. 12, the contact pads 122, 124 can couple with trace portions 1202 to couple with further conductive elements, or as may aid in the alignment of the respective contact pads 122, 124.

FIGS. 13 and 14 depict top views of an arrangement for interconnect structures 120 and contact pads 122, 124 for a gate structure 128 and drain/source regions 130 of a transistor, in accordance with some embodiments. Referring first to FIG. 13, the transparent view depicts a first assembly 1302 and second assembly 1304 provided according to the top view of FIG. 4. These assemblies can include contacts 122, 124 to couple with a drain/source 130 of the transistor. A third assembly 1306 includes contacts 122, 124 coupled with a gate structure 128 for the same transistor (e.g., a polysilicon or metal gate structure 128).

In some embodiments, as is depicted, the gate structure 128 or a via structure 126 coupled therewith may not be laterally enveloped by a contact pad 122, 124. For example, the contact pad 122, 124 can couple with the via structure 126 via a trace portion 1202 separating the contact pad 122, 124 from the via structure 126. In some instances, the relatively low gate currents may not be associated with the electromigration risk associated with the source/drain contacts. However, in some embodiments, gate currents can be somewhat higher, or the contact pads 122, 124 for the gate drive current can laterally envelop coupled proximal via structures 126 as may reduce risk from other manufacturing variance (e.g., voids or over etch). Conversely, as depicted, the use of the trace portion 1202 rather than a substantially larger contact pad 122, 124 may better conform to some design rule checks (DRC), or aid in density of interconnects or their routing, relative to other approaches (e.g., can reduce metallization density for a layer).

In some embodiments, a subset of transistor nodes are coupled along a particular substrate junction (e.g., with TSVs or other interconnect structures 120). For example, at least one source/drain may be coupled between a substrate pair, while a gate or other source/drain may be coupled along the surface of one of the substrate pair, or with a further substrate.

Referring to FIG. 14, a top view of a layout of the conductive elements of a transistor are depicted, as inverted relative to FIG. 13. Particularity, a first assembly 1402, second assembly 1404, and third assembly 1406 are provided, mirroring the first assembly 1302, second assembly 1304, and third assembly 1306 across a first axis of symmetry. A further embodiment may reflect the conductive elements across another axis of symmetry (e.g., perpendicular to the first axis of symmetry).

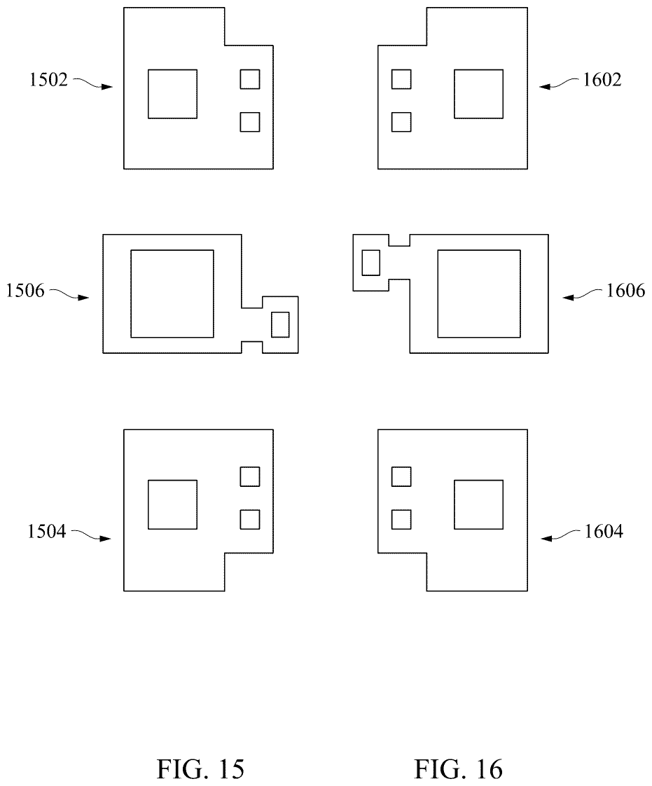

FIGS. 15 and 16 depict top views of another arrangement for interconnect structures 120 and contact pads 122, 124 for a gate, drain, and source of a transistor, in accordance with some embodiments. FIG. 15 depicts a first assembly 1502 and second assembly 1504 of inverted instances of the stack-up provided according to FIG. 6. A third assembly 1506 for the gate is provided as similar to the third assembly 1306, 1406 of FIGS. 13-14 (depicted as rotated therefrom). FIG. 16 depicts an inverted instance of FIG. 15, such that a first assembly 1602, second assembly 1604, and third assembly 1606 are provided as inverted from the first assembly 1502, second assembly 1504, and third assembly 1506 of FIG. 15.

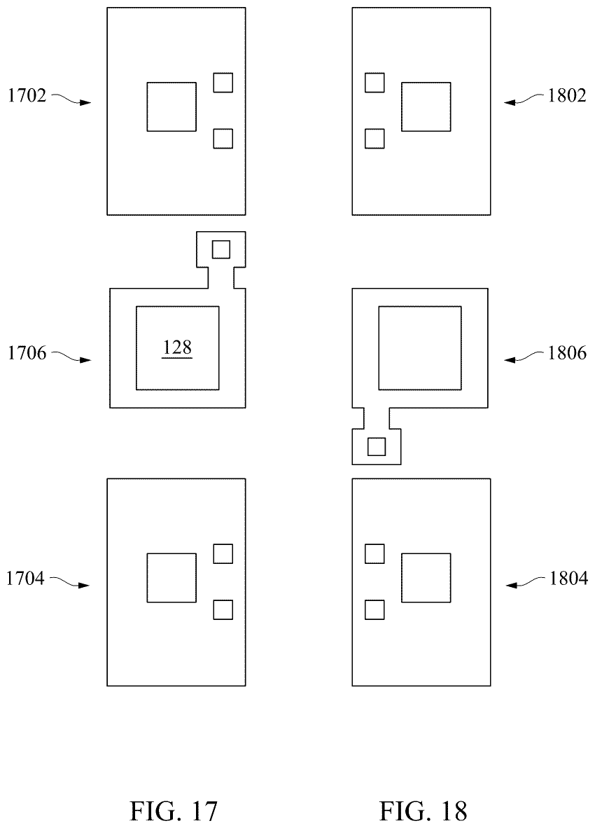

FIGS. 17 and 18 depict additional top views of a further arrangement for interconnect structures 120 and contact pads 122, 124 for a gate, drain, and source of a transistor, in accordance with some embodiments. Particularly, a first assembly 1702 and second assembly 1704 of FIG. 17 are provided as corresponding to the top view of FIG. 8. A third assembly 1706 for the gate structure 128 is provided similarly to the third assembly 1306 of FIG. 13. FIG. 18 is depicted as inverted from FIG. 17, so as to include an inverted first assembly 1802, second assembly 1804, and third assembly 1806.

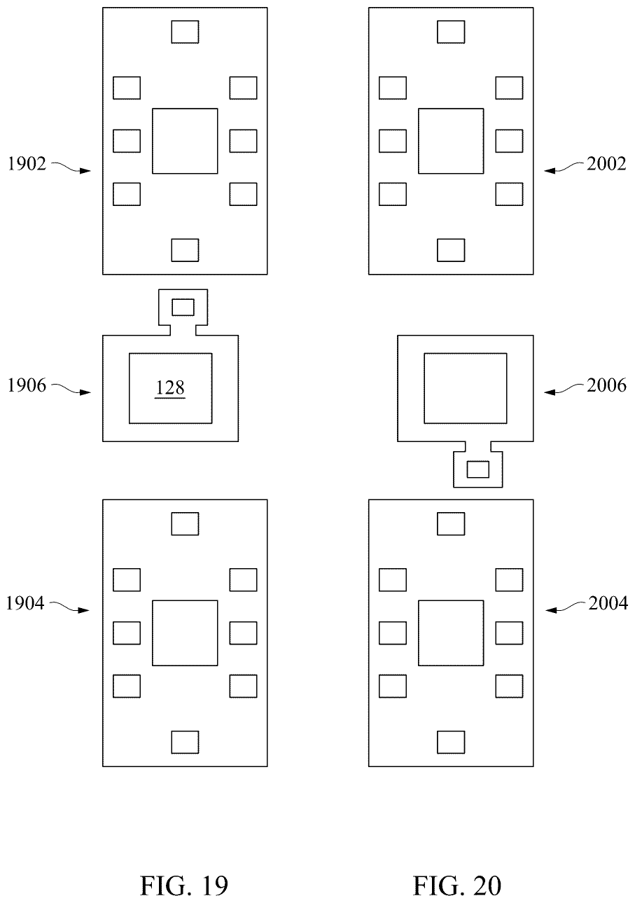

FIGS. 19 and 20 depict additional top views of a yet another arrangement for interconnect structures 120 and contact pads 122, 124 for a gate, drain, and source of a transistor, in accordance with some embodiments. A first assembly 1902 and second assembly 1904 of FIG. 19 are provided as corresponding to the top view of FIG. 10. A third assembly 1906 for the gate structure 128 is provided similarly to the third assembly 1306 of FIG. 13. FIG. 20 is depicted as inverted from FIG. 19, so as to include an inverted first assembly 2002, second assembly 2004, and third assembly 2006.

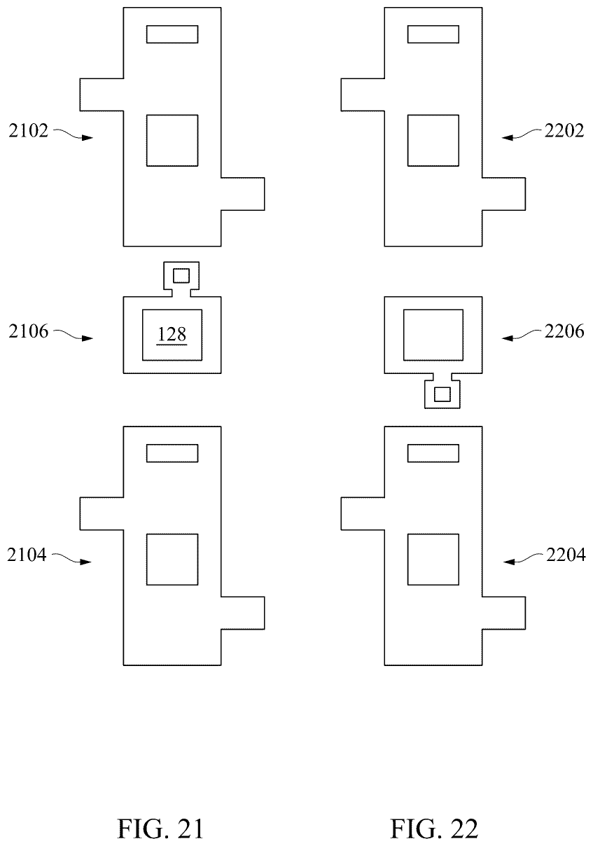

FIGS. 21 and 22 depict additional top views of another arrangement still, for interconnect structures 120 and contact pads 122, 124 for a gate, drain, and source of a transistor, in accordance with some embodiments. A first assembly 2102 and second assembly 2104 of FIG. 21 are provided as corresponding to the top view of FIG. 12. A third assembly 2106 for the gate structure 128 is provided similarly to the third assembly 1306 of FIG. 13. FIG. 22 is depicted as inverted from FIG. 21, so as to include an inverted first assembly 2202, second assembly 2204, and third assembly 2206.

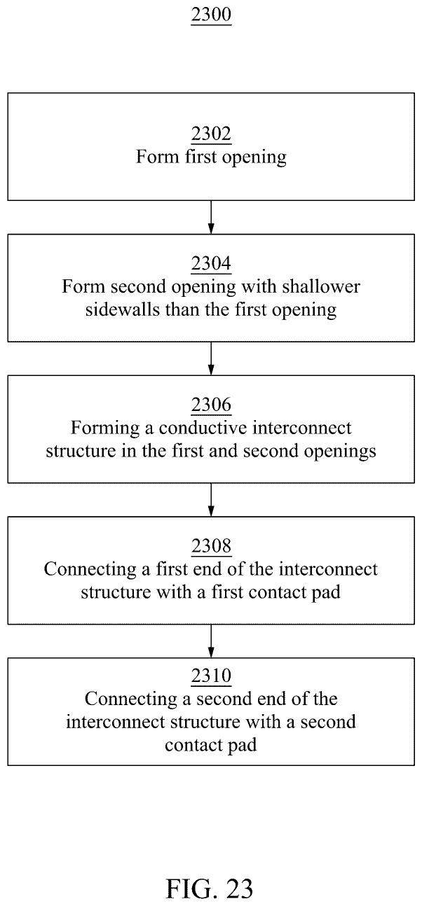

FIG. 23 illustrates a flow chart of a method 2300 for fabricating a semiconductor device 100, in accordance with some embodiments. The method 2300 is merely an example, and is not intended to limit the present disclosure. Accordingly, it should be understood that additional operations may be provided before, during, or after the method 2300 of FIG. 23, and that some other operations may only be briefly described herein.

The method 2300 includes, at operation 2302, forming a first opening. Sidewalls of the opening are formed with a first profile in a substrate. The first profile can be substantially vertical, such as having less than one degree of negative taper. For example, the first opening can correspond to the (uppermost) third portion 202 of various of the interconnect structures 120 provided herein.

The method 2300 includes, at operation 2304, forming a second opening having sidewalls of a second profile, shallower than the first profile, in the substrate. In some embodiments, the second opening is formed by expanding a portion of the first opening. For example, a longitudinal portion of the first opening can be expanded conically from the first opening (e.g., along sidewalls exhibiting a negative taper greater than the first opening). In some embodiments, openings can be expanded to form additional portions. For example, a portion of the longitudinal length of the second opening can be expanded to form a third opening (e.g., the first, second, and third openings can correspond to the first vertical dimension 202, second vertical dimension 204, and third vertical dimension 206). In some embodiments, the various openings are formed end-to-end with one another (e.g., so that the first and second openings are longitudinally adjacent, the second and third openings are longitudinally adjacent, and so forth).

The method 2300 includes, at operation 2306, forming a conductive interconnect structure 120 in the first opening and the second opening. For example, the conductive interconnect structure 120 can be formed according to a metal deposition process. In some embodiments, the metal includes tungsten, aluminum, or copper, and may be configured to couple with a contact pad of a same or different material (e.g., a tungsten or aluminum including contact).

The method 2300 includes, at operation 2308, connecting a first end of the conductive interconnect structure 120 with a first conductive contact pad, the first end of the conductive interconnect structure 120 having a first lateral dimension. For example, the first end may refer to a foot of an interconnect structure 120, and the contact pad 122 may refer to a contact pad 122 disposed along a surface of the substrate.

The method 2300 includes, at operation 2310, connecting a second end (e.g., a narrow tip) of the conductive interconnect structure 120 with a second conductive contact pad. For example, the second conductive contact pad can refer to or include various conductive elements, such as conductive elements disposed in metallization layers of the substate. Such conductive elements can couple with transistors of the substrate, in some embodiments.

As described above, the second end of the conductive interconnect structure 120 can have a second lateral dimension less than the first lateral dimension. The second end can pass near other components of a semiconductor device 100 such that the lesser dimension can aid in device density. For example, the first lateral dimension may couple or interfere with another component. Such other components can include, for example, conductive interconnects of a metallization layer, a well region (e.g., a P-well or an N-well), or another component. A portion of the conductive interconnect structure 120 formed in the first opening may by spaced from an element (e.g., the other component) by a distance of less than half of a difference between the first lateral dimension and the second lateral dimension. That is, if the narrower portion of the interconnect structure 120 was substituted with the wider portion of the interconnect structure 120, the interconnect structure 120 may contact other elements.

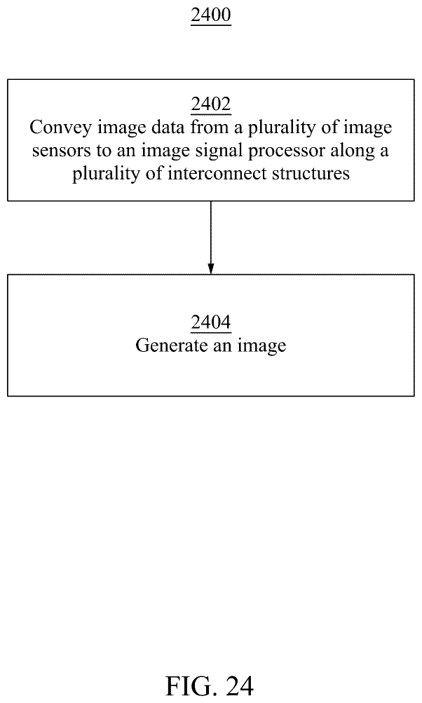

FIG. 24 illustrates a flow chart of a method 2400 for operating a camera system, in accordance with some embodiments. The method 2400 is merely an example, and is not intended to limit the present disclosure. Accordingly, it should be understood that additional operations may be provided before, during, or after the method 2400 of FIG. 24, and that some other operations may only be briefly described herein.

The method 2400 includes, at operation 2402, conveying image data from multiple image sensors 116 to an ISP 118 along a plurality of interconnect structures 120. The interconnect structures 120 can include various of the interconnect structures 120 disclosed herein, such as TSVs. For example, in some embodiments, the image sensors 116 are disposed on a first substrate, and the ISP 118 is disposed on a second substrate. The first substrate is bonded with the second substrate. For example, the first substrate and second substrate can each couple with a third substrate, the third substrate separating the first substrate from the second substrate. In some embodiments, the third substrate includes a plurality of transistors coupled with the ISP 118 via interconnect structures 120 passing through a body of the second substrate (e.g., the interconnect structures 120 can include TSV of the second substrate).

The method 2400 includes, at operation 2404, generating an image. For example, the ISP 118 can generate the image based in image data received from the received image data. In some embodiments, the ISP 118 can modulate an input signal by providing a modulation signal as passed along one of the interconnect structures 120 (e.g., to transistors coupled with the image sensors 116). In some embodiments, the method 2400 includes additional or fewer operations. For example, the method 2400 can omit operation 2404, or may include further operations.

In some aspects, the techniques described herein relate to a semiconductor device, including: a substrate including a plurality of first contact pads disposed on a first surface, and a plurality of second contact pads disposed on a second surface, the substrate including a plurality of interconnect structures extending between the first surface and the second surface; a first portion of an axial extension of the plurality of interconnect structures having sidewalls of a first profile; and a second portion of the axial extension of the plurality of interconnect structures having sidewalls of a second profile, shallower than the first profile.

In some aspects, the techniques described herein relate to a semiconductor device, wherein: the first surface is disposed in a first metallization layer of the substrate; and the second surface is disposed on a backside of the substrate, and the plurality of second contact pads are coupled with a second metallization layer of a second substrate.

In some aspects, the techniques described herein relate to a semiconductor device, wherein the second substrate includes an image signal processor, and the first metallization layer of the substrate is coupled with a third metallization layer of a third substrate, the third substrate including a plurality of image sensors, the plurality of interconnect structures electrically coupling the plurality of image sensors with the image signal processor.

In some aspects, the techniques described herein relate to a semiconductor device, wherein: a third contact pad of the second metallization layer couples with, and laterally envelopes a plurality of via structures of the second metallization layer.

In some aspects, the techniques described herein relate to a semiconductor device, wherein: a third contact pad of the second metallization layer couples with, and laterally envelopes rectangular via structures of the second metallization layer.

In some aspects, the techniques described herein relate to a semiconductor device, wherein a first lateral dimension at a first vertical position of one or more of the plurality of interconnect structures, perpendicular to the axial extension of the one or more interconnect structures, exceeds a distance between conductive elements bounding the one or more interconnect structures at a second vertical position vertically spaced from the first vertical position.

In some aspects, the techniques described herein relate to a semiconductor device, including a third portion having sidewalls of a third profile of the axial extension between the first portion and the second portion, wherein: a first angle of the first profile is less than about one degree; a second angle of the second profile is less than about ten degrees and greater than about one degrees; and a third angle of the third profile is greater than the first angle and less than the second angle.

In some aspects, the techniques described herein relate to a semiconductor device, wherein: a length of the first portion of the axial extension is greater than about fifty micrometers (μm); a length of the second portion of the axial extension is between about one μm and about five μm; and a length of the third portion of the axial extension is between about five μm and about ten μm.

In some aspects, the techniques described herein relate to a semiconductor device, wherein a pitch between at least two of the plurality of interconnect structures is less than about seven μm.

In some aspects, the techniques described herein relate to a semiconductor device, wherein: the plurality of interconnect structures include tungsten, aluminum, or copper; and the plurality of second contact pads include tungsten or aluminum.

In some aspects, the techniques described herein relate to a method of fabricating a semiconductor device, including: forming a first opening having sidewalls of a first profile in a substrate; forming a second opening having sidewalls of a second profile, shallower than the first profile, in the substrate; forming a conductive interconnect structure in the first opening and the second opening; connecting a first end of the conductive interconnect structure with a first conductive contact pad, the first end of the conductive interconnect structure having a first lateral dimension; and connecting a second end of the conductive interconnect structure with a second conductive contact pad, the second end of the conductive interconnect structure having a second lateral dimension, lesser than the first lateral dimension, wherein a portion of the conductive interconnect structure formed in the first opening is spaced from a different conductive element by a distance of less than half of a difference between the first lateral dimension and the second lateral dimension.

In some aspects, the techniques described herein relate to a method, further including: coupling the first conductive contact pad with an image sensor; and coupling the second conductive contact pad with an image signal processor.

In some aspects, the techniques described herein relate to a method, further including: coupling the conductive interconnect structure with one of a polycrystalline silicon gate or a metal for a transistor, the transistor coupling an image sensor with an image signal processor.

In some aspects, the techniques described herein relate to a method, including a third portion having sidewalls of a third profile of an axial extension between a first portion of the conductive interconnect structure and a second portion of the conductive interconnect structure, wherein: a first angle of the first profile is less than about one degree; a second angle of the second profile is less than about ten degrees and greater than about one degrees; and a third angle of the third profile is greater than the first angle and less than the second angle.

In some aspects, the techniques described herein relate to a method, wherein: a length of the first portion of the axial extension is greater than about fifty micrometers (μm); a length of the second portion of the axial extension is between about one μm and about five μm; and a length of the third portion of the axial extension is between about five μm and about ten μm.

In some aspects, the techniques described herein relate to a method, wherein a pitch between the conductive interconnect structure and a further conductive interconnect structure is less than about seven μm.

In some aspects, the techniques described herein relate to a method, wherein: the conductive interconnect structure includes tungsten, aluminum, or copper; and the second conductive contact pad includes tungsten or aluminum.

In some aspects, the techniques described herein relate to a camera system, including: a first substrate including a plurality of image sensors; a second substrate including an image signal processor, the image signal processor coupled with the plurality of image sensors via a plurality of interconnect structures extending, axially between the first substrate and the second substrate, the plurality of interconnect structures including: a first portion of an axial extension having sidewalls of a first profile, the first portion proximal to the plurality of image sensors; and a second portion of the axial extension having sidewalls of a second profile, shallower than the first profile, the first portion proximal to the image signal processor.

In some aspects, the techniques described herein relate to a camera system, wherein: the plurality of interconnect structures extends through a third substrate disposed between the first substrate and the second substrate, the third substrate including a plurality of transistors coupled with the plurality of image sensors, the plurality of interconnect structures coupled with the plurality of transistors at a first end and with the image signal processor at a second end.

In some aspects, the techniques described herein relate to a camera system, wherein the plurality of interconnect structures couple with a contact pad of the second substrate, a body of the contact pad enveloping a plurality of via structures coupled with the image signal processor.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprising a plurality of first contact pads disposed on a first surface, and a plurality of second contact pads disposed on a second surface, the substrate comprising a plurality of interconnect structures extending between the first surface and the second surface;
a first portion of an axial extension of the plurality of interconnect structures having sidewalls of a first profile; and
a second portion of the axial extension of the plurality of interconnect structures having sidewalls of a second profile, shallower than the first profile.

2. The semiconductor device of claim 1, wherein:
the first surface is disposed in a first metallization layer of the substrate; and
the second surface is disposed on a backside of the substrate, and the plurality of second contact pads are coupled with a second metallization layer of a second substrate.

3. The semiconductor device of claim 2, wherein the second substrate comprises an image signal processor, and the first metallization layer of the substrate is coupled with a third metallization layer of a third substrate, the third substrate comprising a plurality of image sensors, the plurality of interconnect structures electrically coupling the plurality of image sensors with the image signal processor.

4. The semiconductor device of claim 2, wherein:
a third contact pad of the second metallization layer couples with, and laterally envelopes a plurality of via structures of the second metallization layer.

5. The semiconductor device of claim 2, wherein:
a third contact pad of the second metallization layer couples with, and laterally envelopes rectangular via structures of the second metallization layer.

6. The semiconductor device of claim 1, wherein a first lateral dimension at a first vertical position of one or more of the plurality of interconnect structures, perpendicular to the axial extension of the one or more interconnect structures, exceeds a distance between conductive elements bounding the one or more interconnect structures at a second vertical position vertically spaced from the first vertical position.

7. The semiconductor device of claim 1, comprising a third portion having sidewalls of a third profile of the axial extension between the first portion and the second portion, wherein:
a first angle of the first profile is less than about one degree;
a second angle of the second profile is less than about ten degrees and greater than about one degree; and
a third angle of the third profile is greater than the first angle and less than the second angle.

8. The semiconductor device of claim 7, wherein:
a length of the first portion of the axial extension is greater than about fifty micrometers (μm);
a length of the second portion of the axial extension is between about one μm and about five μm; and
a length of the third portion of the axial extension is between about five μm and about ten μm.

9. The semiconductor device of claim 7, wherein a pitch between at least two of the plurality of interconnect structures is less than about seven μm.

10. The semiconductor device of claim 7, wherein:
the plurality of interconnect structures comprise tungsten, aluminum, or copper; and
the plurality of second contact pads comprise tungsten or aluminum.

11. A method of fabricating a semiconductor device, comprising:
forming a first opening having sidewalls of a first profile in a substrate;
forming a second opening having sidewalls of a second profile, shallower than the first profile, in the substrate;
forming a conductive interconnect structure in the first opening and the second opening;
connecting a first end of the conductive interconnect structure with a first conductive contact pad, the first end of the conductive interconnect structure having a first lateral dimension; and
connecting a second end of the conductive interconnect structure with a second conductive contact pad, the second end of the conductive interconnect structure having a second lateral dimension, lesser than the first lateral dimension, wherein a portion of the conductive interconnect structure formed in the first opening is spaced from a different conductive element by a distance of less than half of a difference between the first lateral dimension and the second lateral dimension.

12. The method of claim 11, further comprising:
coupling the first conductive contact pad with an image sensor; and
coupling the second conductive contact pad with an image signal processor.

13. The method of claim 11, further comprising:
coupling the conductive interconnect structure with one of a polycrystalline silicon gate or a metal for a transistor, the transistor coupling an image sensor with an image signal processor.

14. The method of claim 11, comprising a third portion having sidewalls of a third profile of an axial extension between a first portion of the conductive interconnect structure and a second portion of the conductive interconnect structure, wherein:
a first angle of the first profile is less than about one degree;
a second angle of the second profile is less than about ten degrees and greater than about one degree; and
a third angle of the third profile is greater than the first angle and less than the second angle.

15. The method of claim 14, wherein:
a length of the first portion of the axial extension is greater than about fifty micrometers (μm);
a length of the second portion of the axial extension is between about one μm and about five μm; and
a length of the third portion of the axial extension is between about five μm and about ten μm.

16. The method of claim 15, wherein a pitch between the conductive interconnect structure and a further conductive interconnect structure is less than about seven μm.

17. The method of claim 15, wherein:
the conductive interconnect structure comprises tungsten, aluminum, or copper; and
the second conductive contact pad comprises tungsten or aluminum.

18. A camera system, comprising:
a first substrate comprising a plurality of image sensors; and
a second substrate comprising an image signal processor, the image signal processor coupled with the plurality of image sensors via a plurality of interconnect structures extending, axially between the first substrate and the second substrate, the plurality of interconnect structures comprising:
a first portion of an axial extension having sidewalls of a first profile, the first portion proximal to the plurality of image sensors; and
a second portion of the axial extension having sidewalls of a second profile, shallower than the first profile, the first portion proximal to the image signal processor.

19. The camera system of claim 18, wherein:
the plurality of interconnect structures extends through a third substrate disposed between the first substrate and the second substrate, the third substrate comprising a plurality of transistors coupled with the plurality of image sensors, the plurality of interconnect structures coupled with the plurality of transistors at a first end and with the image signal processor at a second end.

20. The camera system of claim 19, wherein the plurality of interconnect structures couple with a contact pad of the second substrate, a body of the contact pad enveloping a plurality of via structures coupled with the image signal processor.
